(19) United States
(12) Patent Application Publication
(10) Pub. No.: US 2025/0072080 A1
(43) Pub. Date: Feb. 27, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chang-Yih Chen, Tainan City (TW); Yi-Wen Chen, Chiayi County (TW); Chia-Chen Sun, Kaohsiung City (TW); Wei-Chung Sun, Tainan City (TW); Wan-Ching Lee, Tainan City (TW)

(73) Assignee: UNITED MICROELECTRONICS CORP., Hsin-Chu City (TW)

(21) Appl. No.: 18/372,684

(22) Filed: Sep. 25, 2023

(30) Foreign Application Priority Data
Aug. 24, 2023 (TW) 112131892

(51) Int. Cl. H01L 29/66; H01L 21/8238; H01L 27/092; H01L 29/08

(52) U.S. Cl. CPC H01L 29/6656; H01L 21/823814; H01L 21/823828; H01L 21/823864; H01L 27/092; H01L 29/0847; H01L 29/66545

(57) ABSTRACT

A method for fabricating a semiconductor device includes the steps of first forming a gate structure on a substrate, forming a first spacer on the gate structure, forming a patterned mask on the gate structure and one side of the gate structure, removing the first spacer on another side of the gate structure, and then forming a source/drain region adjacent to two sides of the gate structure.

### BACKGROUND OF THE INVENTION

### 1. Field of the Invention

The invention relates to a method for fabricating semiconductor device, and more particularly, to a method of forming asymmetric gate dielectric layer.

### 2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in current fabrication of high-k metal gate transistor in particularly during the formation of medium-voltage (MV) devices when doped regions such as lightly doped drains (LDDs) or source/drain regions are too close to the gate electrode, problem such as gate-induced-drain-leakage (GIDL) often arise. Hence, how to resolve this issue has become an important task in this field.

### SUMMARY OF THE INVENTION

According to an embodiment of the present invention, a method for fabricating a semiconductor device includes the steps of first forming a gate structure on a substrate, forming a first spacer on the gate structure, forming a patterned mask on the gate structure and one side of the gate structure, removing the first spacer on another side of the gate structure, and then forming a source/drain region adjacent to two sides of the gate structure.

According to another aspect of the present invention, a semiconductor device includes a gate structure on a substrate, a first spacer adjacent to the gate structure, and a second spacer adjacent to the first spacer. Preferably, the gate structure further includes a gate electrode on the substrate and a gate dielectric layer between the substrate and the gate electrode, in which the gate dielectric layer adjacent to one side of the gate electrode and the gate dielectric layer adjacent to another side of the gate electrode are asymmetrical.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating semiconductor device according to an embodiment of the present invention.

FIG. 8 illustrates a structural view of a semiconductor device according to an embodiment of the present invention.

### DETAILED DESCRIPTION

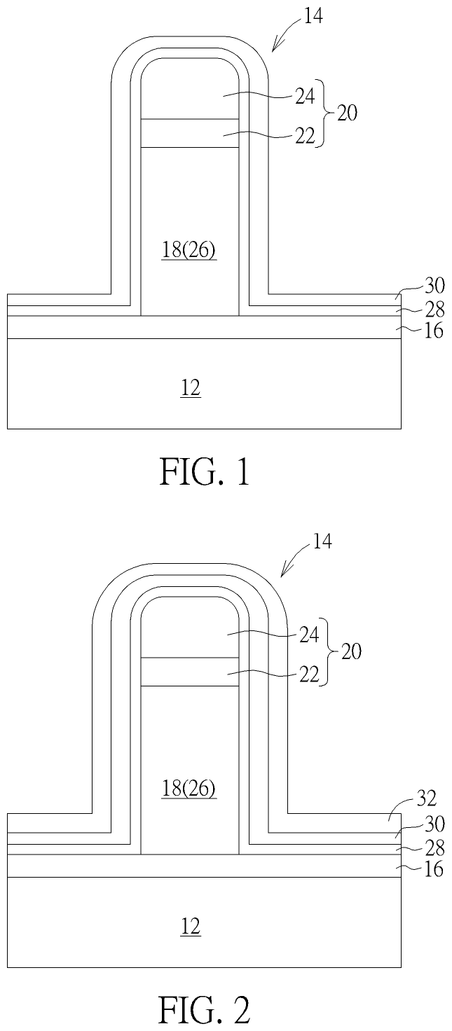

Referring to FIGS. 1-7, FIGS. 1-7 illustrate a method for fabricating semiconductor device according to an embodiment of the present invention. As shown in FIG. 1, a substrate 12 is first provided, in which the substrate could be a silicon substrate or silicon-on-insulator (SOI) substrate. A transistor region used for preparing a MV device could be defined on the substrate 12, in which the transistor region could further include a PMOS region or a NMOS region. It should be noted that even though the present invention pertains to a method for fabricating planar field effect transistor (FET), according to other embodiment of the present invention, the following process could also be employed for fabricating non-planar devices such as fin field effect transistor (FinFET) device. In this instance, the substrate 12 shown in FIG. 1 would then be a fin-shaped structure disposed on the substrate 12.

According to an embodiment of the present invention, the fin-shaped structures could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures could also be obtained by first forming a patterned mask (not shown) on the substrate, 12, and through an etching process, the pattern of the patterned mask is transferred to the substrate 12 to form the fin-shaped structure. Moreover, the formation of the fin-shaped structures could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures. These approaches for forming fin-shaped structures are all within the scope of the present invention.

Next, at least a gate structure 14 or dummy gate is formed on the substrate 12. In this embodiment, the formation of the gate structure 14 could be accomplished by a gate first process, a high-k first approach from gate last process, or a high-k last approach from gate last process. Since this embodiment pertains to a high-k last approach, a gate dielectric layer 16 or interfacial layer, a gate material layer 18 made of polysilicon, and a selective hard mask 20 could be formed sequentially on the substrate 12, and a pattern transfer process is conducted by using a patterned resist (not shown) as mask to remove part of the hard mask 20, part of the gate material layer 18, and part of the gate dielectric layer 16 through single or multiple etching processes. After stripping the patterned resist, a gate structure 14 made of a patterned gate dielectric layer 16, a patterned gate material layer 18, and a patterned hard mask 20 are formed on the substrate 12. Preferably, the gate material layer 18 could be serving as a gate electrode 26 and the hard mask 20 could be made of a dual-layer structure, in which the bottom hard mask 22 includes silicon nitride while the top hard mask 24 includes silicon oxide, but not limited thereto.

Next, a first spacer 28 is formed on the gate structure 14 including the top surface of the gate structure 14, sidewalls of the gate structure 14, and the surface of the gate dielectric layer 16 adjacent to two sides of the gate structure 14, and then a second spacer 30 is formed on the first spacer 28. In this embodiment, the first spacer 28 and the second spacer 30 both include SiOCN. Nevertheless, according to other embodiment of the present invention, the first spacer 28 and the second spacer 30 could also be made of same or different material depending on the demand of the process as both spacers 28, 30 could all be selected from the group consisting of SiO₂. SiN, SiON, and SiCN, which are all within the scope of the present invention.

Next, as shown in FIG. 2, a sacrificial layer 32 is formed on the second spacer 30, in which the sacrificial layer 32 preferably includes SiN, but not limited thereto.

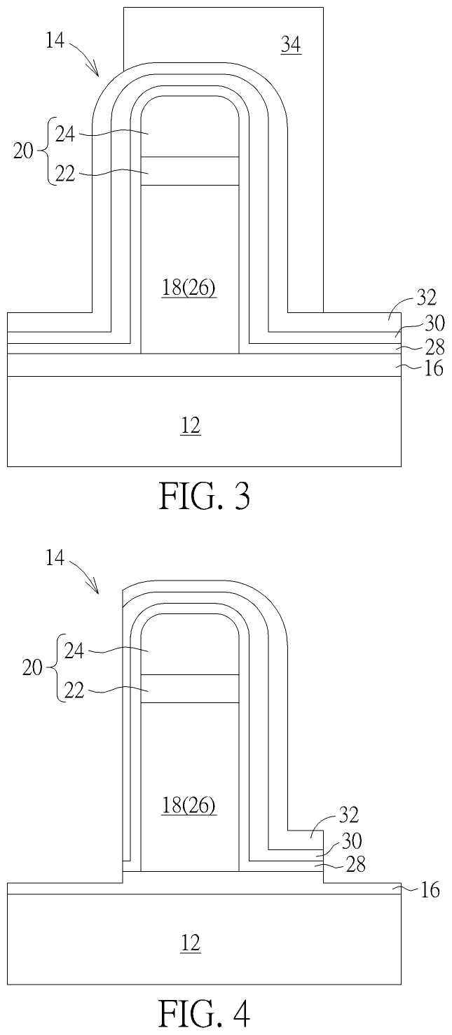

Next, as shown in FIG. 3, a photo-etching process is conducted to remove the sacrificial layer 32, the second spacer 30, and the first spacer 28 adjacent to one side of the gate structure 14. Specifically, the photo-etching process could be accomplished by first forming a patterned mask 34 such as a patterned resist directly on top of the gate structure 14 as well as one side such as right side of the gate structure 14, in which the patterned mask 34 exposes majority of the sacrificial layer 32 adjacent to another side such as left side of the gate structure 14 and a small portion of the sacrificial layer 32 on the right side.

Next, as shown in FIG. 4, an etching process is conducted by using the patterned mask 34 as mask to remove part of the sacrificial layer 32, part of the second spacer 30, part of the first spacer 28, and part of the gate dielectric layer 16 adjacent to left and right side of the gate structure 14 so that the remaining gate dielectric layer 16, first spacer 28, second spacer 30, and sacrificial layer 32 on left and right side of the gate structure 14 form an asymmetric structure. Specifically, the etching process conducted at this stage removes all of the vertical portion and horizontal portion of the sacrificial layer 32, part of the vertical portion and horizontal portion of the second spacer 30, part of the horizontal portion of the first spacer 28, and part of the gate dielectric layer 16 on left side of the gate structure 14 so that the sidewall of the remaining sacrificial layer 32 is aligned with sidewall of the vertical portion of the second spacer 30, sidewall of the horizontal portion of the first spacer 28, and sidewall of the gate dielectric layer 16 underneath.

In contrast to removing vertical portions of the sacrificial layer 32 and second spacer 30 on left side of the gate structure 14, only a small portion of the horizontal portion of the sacrificial layer 32, second spacer 30, and first spacer 28 on right side of the gate structure 14 is removed, in which the width of the remaining sacrificial layer 32 on left side of the gate structure 14 is less than the width of the remaining sacrificial layer 32 on right side of the gate structure 14, the width of the remaining second spacer 30 on left side of the gate structure 14 is less than the width of the remaining second spacer 30 on right side of the gate structure 14, the width of the remaining first spacer 28 on left side of the gate structure 14 is less than the width of the remaining first spacer 28 on right side of the gate structure 14, and the width of the remaining gate dielectric layer 16 on left side of the gate structure 14 is less than the width of the remaining gate dielectric layer 16 on right side of the gate structure 14.

According to an embodiment of the present invention, the so-called width of each spacer or material layer could be defined as a maximum distance measuring from an outer sidewall of each spacer or material layer along the horizontal or X-direction to an inner sidewall of each spacer or to the sidewall of the gate structure 14. For instance, the width of the remaining sacrificial layer 32 on left side of the gate structure 14 could be the width extending from the left sidewall of the sacrificial layer 32 to the left sidewall of the gate structure 14, the width of the remaining second spacer 30 on left side of the gate structure 14 could be the width extending from the left sidewall of the second spacer 30 to the right sidewall of the second spacer 30, the width of the remaining first spacer 28 on left side of the gate structure 14 could be the width extending from the left sidewall of the first spacer 30 aligned with sidewall of the second spacer 30 to the right sidewall of the first spacer 28, and the width of the remaining gate dielectric layer 16 on left side of the gate structure 14 could be the width extending from the left sidewall of the gate dielectric layer 16 aligned with sidewall of the second spacer 30 to the left sidewall of the gate structure 14.

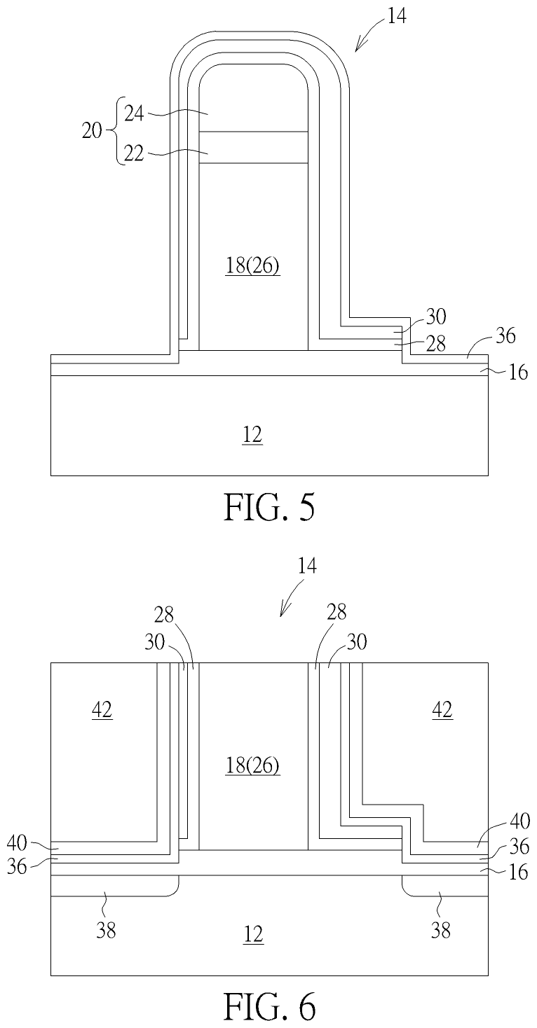

Next, as shown in FIG. 5, an etching process is conducted to remove the sacrificial layer 32 and then form a third spacer 36 on the second spacer 30, in which the third spacer 36 is disposed on top surface and sidewalls of the second spacer 20, sidewalls of the first spacer 28, and surface of the gate dielectric layer 16 adjacent to two sides of the gate structure 14. In this embodiment, the third spacer 36 preferably includes silicon oxide, but not limited thereto. According to other embodiment of the present invention, the first spacer 28, the second spacer 30, the sacrificial layer 32, and the third spacer 36 could all be selected from the group consisting of SiO₂, SiN, SiON, and SiCN, which are all within the scope of the present invention.

Next, as shown in FIG. 6, an ion implantation process is conducted to implant n-type or p-type dopants into the substrate 12 adjacent to two sides of the gate structure 14 for forming a source/drain region 38, in which the source/drain region 38 on left side of the gate structure 14 is preferably a source region while the source/drain region 38 on right side of the gate structure 14 is a drain region. Next, a contact etch stop layer (CESL) 40 made of SiN is formed on surface of the third spacer 36 and an interlayer dielectric (ILD) layer 42 is formed on the CESL 40. Next, a planarizing process such as CMP is conducted to remove part of the ILD layer 42, part of the CESL 40, part of the third spacer 36, part of the second spacer 30, part of the first spacer 28, and all of the hard mask 20 for exposing the gate material layer 18 made of polysilicon so that the top surface of the gate material layer 18 is even with the top surface of the ILD layer 42.

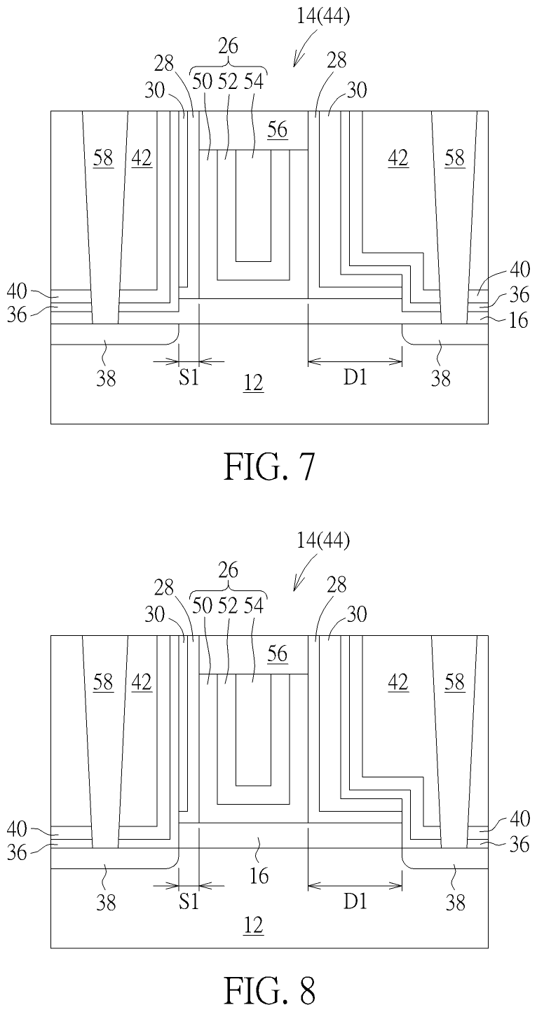

Next, as shown in FIG. 7, a replacement metal gate (RMG) process is conducted to transform the gate structure 14 into metal gate 44. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 18 for forming a recess (not shown) in the ILD layer 42.

Next, a selective interfacial layer (not shown), a high-k dielectric layer 50, a work function metal layer 52, and a low resistance metal layer 54 are formed in the recess, and a planarizing process such as CMP is conducted to remove part of low resistance metal layer 54, part of work function metal layer 52, and part of high-k dielectric layer 50 to form a metal gate 44. In this embodiment, the gate electrode 26 from the metal gate 44 fabricated through high-k last process of a gate last process preferably includes an U-shaped high-k dielectric layer 50, a U-shaped work function metal layer 52, and a low resistance metal layer 54.

In this embodiment, the high-k dielectric layer 50 is preferably selected from dielectric materials having dielectric constant (k value) larger than 4. For instance, the high-k dielectric layer 60 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBizTa₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 52 is formed for tuning the work function of the metal gate in accordance with the conductivity of the device. For an NMOS transistor, the work function metal layer 52 having a work function ranging between 3.9 cV and 4.3 cV may include titanium aluminide (TiAl), zirconium aluminide (ZrAl), tungsten aluminide (WAI), tantalum aluminide (TaAl), hafnium aluminide (HfAl), or titanium aluminum carbide (TiAIC), but it is not limited thereto. For a PMOS transistor, the work function metal layer 52 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 52 and the low resistance metal layer 54, in which the material of the barrier layer may include titanium (Ti), titanium nitride (TiN), tantalum (Ta) or tantalum nitride (TaN). Furthermore, the material of the low-resistance metal layer 54 may include copper (Cu), aluminum (Al), titanium aluminum (TiAl), cobalt tungsten phosphide (CoWP) or any combination thereof.

Next, part of the low resistance metal layer 54, part of the work function metal layer 52, and part of the high-k dielectric layer 50 could be removed to form a recess (not shown), a hard mask 56 is formed into the recess, and a planarizing process is conducted so that the top surface of the hard mask 56 is even with the top surface of the ILD layer 42. In this embodiment, the hard mask 56 could be selected from the group consisting of consisting of SiO₂, SiN, SiON, and SiCN.

Next, a photo-etching process is conducted by using a patterned mask (not shown) as mask to remove part of the ILD layer 42, part of the CESL 40, part of the third spacer 36, and part of the gate dielectric layer 16 for forming contact holes (not shown) exposing the source/drain region 38. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 58 electrically connecting the source/drain region 38. This completes the fabrication of a semiconductor device according to an embodiment of the present invention.

Referring again to FIG. 7, FIG. 7 further illustrates a structural view of a semiconductor device according to an embodiment of the present invention. As shown in FIG. 7, the semiconductor device includes a gate structure 14 disposed on the substrate 12, a first spacer 28 disposed adjacent to the gate structure 14, a second spacer 30 disposed adjacent to the first spacer 28, a third spacer 36 disposed adjacent to the second spacer 30, and a source/drain region 38 disposed in the substrate 12 adjacent to two sides of the gate structure 14.

In this embodiment, the gate structure 14 further includes a gate electrode 26 disposed on the substrate 12 and a gate dielectric layer 16 between the substrate 12 and the gate electrode 26, in which the gate dielectric layer 16 adjacent to one side of the gate electrode 26 and the gate dielectric layer 16 adjacent to another side of the gate electrode 26 are asymmetric and the spacer adjacent to one side of the gate electrode 26 and the spacer adjacent to another side of the gate electrode 26 are also asymmetric. For instance, the second spacer 30 on left side of the gate electrode 26 includes an I-shape while the second spacer 30 on right side of the gate electrode 26 includes an L-shape.

Specifically, the width of the second spacer 30 on left side of the gate electrode 26 is less than the width of the second spacer 30 on right side of the gate electrode 26, the width of the first spacer 28 on left side of the gate electrode 26 is less than the width of the first spacer 28 on right side of the gate electrode 26, and the width of the gate dielectric layer 16 aligned with the second spacer 30 on left side of the gate electrode 26 is less than the width of the gate dielectric layer 16 aligned with the second spacer 30 on right side of the gate electrode 26. According to an embodiment of the present invention, the width of the first spacer 28 on right side of the gate electrode 26 is preferably greater than two times, three times, four times, five times, six times, or even seven times of the width of the first spacer 28 on left side of the gate electrode 26 and the width of the second spacer 30 on right side of the gate electrode 26 is also greater than two times, three times, four times, five times, six times, or even seven times of the width of the second spacer 30 on left side of the gate electrode 26.

Moreover, a distance S1 extending from an edge of the left source/drain region 38 or source region to the edge of the gate electrode 26 is less than a distance D1 extending from an edge of the right source/drain region 38 or drain region to the edge of the gate electrode 26. According to an embodiment of the present invention, the distance D1 extending from the edge of the right source/drain region 38 or drain region to the edge of the gate electrode 26 is greater than two times, three times, four times, five times, six times, or even seven times of the distance S1 extending from the edge of the left source/drain region 38 or source region to the edge of the gate electrode 26.

Referring to FIG. 8, FIG. 8 further illustrates a structural view of a semiconductor device according to an embodiment of the present invention. As shown in FIG. 8, in contrast to the gate dielectric layer 16 in FIG. 7 extending from directly under the gate electrode 26 to the surface of the substrate 12 adjacent to two sides of the gate structure 26, it would also be desirable to completely remove the gate dielectric layer 16 adjacent to two sides of the first spacer 28 for exposing the substrate 12 surface when part of the sacrificial layer 32, part of the second spacer 30, part of the first spacer 28, and part of the gate dielectric layer 16 are removed asymmetrically in FIG. 4, and then form the metal gate 44 and contact plugs 58 according to FIGS. 5-7 afterwards. In this instance, the leftmost edge of the gate dielectric layer 16 on left side of the gate electrode 26 would be aligned with the first spacer 28 and second spacer 30 above and the edge of gate dielectric layer 16 on right side of the gate electrode 26 would also be aligned with the first spacer 28 and second spacer 30 above, which is also within the scope of the present invention.

Typically, in current fabrication of medium-voltage (MV) devices when doped regions such as lightly doped drains (LDDs) or source/drain regions are too close to the gate electrode, problem such as gate-induced-drain-leakage (GIDL) often arise. To resolve this issue, the present invention first forms a spacer adjacent to the gate structure, forms a patterned mask directly on top of the gate structure and a majority of the area adjacent to one side of the gate structure, and then conducts an etching process to remove a majority of the spacer and gate dielectric layer adjacent to another side of the gate structure so that the spacer and gate dielectric layer adjacent to two sides of the gate structure form asymmetric structures having different widths and/or different shapes. By using this approach to fabricate MV devices, it would be desirable to significantly reduce the occurrence of GIDL and boost up performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a gate structure on a substrate;
forming a first spacer on the gate structure;
forming a patterned mask on the gate structure and one side of the gate structure;
removing the first spacer on another side of the gate structure; and
forming a source/drain region adjacent to two sides of the gate structure.

2. The method of claim 1, further comprising:
forming a gate dielectric layer on the substrate;
forming a gate material layer on the gate dielectric layer;
patterning the gate material layer to form the gate structure;
forming the first spacer on the gate structure;
forming a second spacer on the first spacer;
forming a sacrificial layer on the second spacer;
removing the sacrificial layer, the second spacer, and the first spacer on another side of the gate structure;
forming a third spacer on the second spacer; and
forming the source/drain region.

3. The method of claim 2, further comprising removing the sacrificial layer completely before forming the third spacer.

4. The method of claim 2, further comprising removing the sacrificial layer, the second spacer, the first spacer, and the gate dielectric layer at the same time.

5. The method of claim 2, wherein the gate dielectric layer adjacent to one side of the gate structure and the gate dielectric layer adjacent to another side of the gate structure are asymmetrical.

6. The method of claim 2, wherein a width of the gate dielectric layer adjacent to one side of the gate structure and a width of the gate dielectric layer adjacent to another side of the gate structure are different.

7. The method of claim 2, wherein a width of the second spacer adjacent to one side of the gate structure and a width of the second spacer adjacent to another side of the gate structure are different.

8. The method of claim 1, further comprising:
forming an interlayer dielectric (ILD) layer around the gate structure; and
performing a replacement metal gate (RMG) process to transform the gate structure into a metal gate.

9. A semiconductor device, comprising:
a gate structure on a substrate, wherein the gate structure comprises:
a gate electrode on the substrate; and
a gate dielectric layer between the substrate and the gate electrode, wherein the gate dielectric layer adjacent to one side of the gate electrode and the gate dielectric layer adjacent to another side of the gate electrode are asymmetrical;
a first spacer adjacent to the gate structure; and
a second spacer adjacent to the first spacer.

10. The semiconductor device of claim 9, wherein a width of the gate dielectric layer adjacent to one side of the gate structure and a width of the gate dielectric layer adjacent to another side of the gate structure are different.

11. The semiconductor device of claim 9, wherein the first spacer adjacent to one side of the gate structure and the first spacer adjacent to another side of the gate structure are asymmetrical.

12. The semiconductor device of claim 9, wherein a width of the first spacer adjacent to one side of the gate structure and a width of the first spacer adjacent to another side of the gate structure are different.

13. The semiconductor device of claim 9, wherein the second spacer adjacent to one side of the gate structure and the second spacer adjacent to another side of the gate structure are asymmetrical.

14. The semiconductor device of claim 9, wherein a width of the second spacer adjacent to one side of the gate structure and a width of the second spacer adjacent to another side of the gate structure are different.

15. The semiconductor device of claim 9, wherein the gate electrode comprises a metal gate.

16. The semiconductor device of claim 9, wherein the gate electrode comprises:
a high-k dielectric layer on the gate dielectric layer;
a work function metal layer on the high-k dielectric layer; and
a low resistance metal layer on the work function metal layer.
